(19) United States
(12) Patent Application Publication
(10) Pub. No.: US 2020/0294861 A1
(43) Pub. Date: Sep. 17, 2020

(54) SEMICONDUCTOR DEVICE AND SEMICONDUCTOR DEVICE MANUFACTURING METHOD

(71) Applicant: TOSHIBA MEMORY CORPORATION, Tokyo (JP)

(72) Inventors: Junya FUJITA, Nagoya Aichi (JP); Ryota FUJITSUKA, Yokkaichi Mie (JP)

(73) Assignee: TOSHIBA MEMORY CORPORATION, Tokyo (JP)

(21) Appl. No.: 16/559,390

(22) Filed: Sep. 3, 2019

(30) Foreign Application Priority Data
Mar. 14, 2019 (JP) 2019-047387

(51) Int. Cl. H01L 21/8234; H01L 21/02; H01L 29/49

(52) U.S. Cl. CPC H01L 21/823462; H01L 29/4941; H01L 21/0214

(57) ABSTRACT

According to one embodiment, a semiconductor device includes: a semiconductor substrate; a gate insulating film provided on the semiconductor substrate; a gate electrode film, provided on the gate insulating film, that includes boron; a side wall insulating film extending along a side surface of the gate electrode film; a barrier film including a first portion provided between the side surface of the gate electrode film and the side wall insulating film, and a second portion, connected to the first portion, that is provided between the gate insulating film and a bottom surface of the side wall insulating film. The barrier film includes carbon as a main component to limit diffusion of the boron in the gate electrode film.

This application is based upon and claims the benefit of priority from Japanese Patent Application No. 2019-047387, filed Mar. 14, 2019, the entire contents of which are incorporated herein by reference.

### FIELD

Embodiments described herein relate generally to a semiconductor device and a method of manufacturing the same.

### BACKGROUND

A P-channel MOS (Metal Oxide Semiconductor) transistor is often provided in peripheral circuits of a semiconductor storage device. As for such a MOS transistor, a technique for doping polysilicon with boron as a gate electrode is known.

When a concentration of boron contained in the gate electrode is high, boron sometimes diffuses to a silicon substrate in, for example, a memory cell heat treatment process performed after manufacturing the MOS transistor. In this case, characteristics of the MOS transistor are possibly adversely influenced by boron. On the other hand, if the concentration of boron is too low, then a depletion layer is formed and an effective gate oxide film thickness increases, with the result that expected transistor performance requirements are not satisfied.

Examples of related art include Japanese Patent No. 5235486.

### DESCRIPTION OF THE DRAWINGS

FIG. 1 is a perspective view depicting a schematic configuration of a semiconductor storage device according to a first embodiment.

FIG. 2 is a cross-sectional view depicting a structure of principal portions of a P-channel MOS transistor according to the first embodiment.

FIG. 3 is a cross-sectional view illustrating a gate insulating film manufacturing process.

FIG. 4 is a cross-sectional view illustrating a gate electrode film manufacturing process.

FIG. 5 is a cross-sectional view illustrating a barrier film manufacturing process.

FIG. 6 is a cross-sectional view illustrating a side wall insulating film manufacturing process.

FIG. 7 is a cross-sectional view depicting a structure of principal portions of a P-channel MOS transistor according to a second embodiment.

### DETAILED DESCRIPTION

Embodiments provide a semiconductor device and a semiconductor device manufacturing method capable of suppressing diffusion of boron while reducing depletion of a gate electrode.

In general, according to one embodiment, a semiconductor device includes: a semiconductor substrate; a gate insulating film provided on the semiconductor substrate; a gate electrode film, provided on the gate insulating film, that includes boron; a side wall insulating film extending along a side surface of the gate electrode film; a barrier film including a first portion provided between the side surface of the gate electrode film and the side wall insulating film, and a second portion, connected to the first portion, that is provided between the gate insulating film and a bottom surface of the side wall insulating film. The barrier film includes carbon as a main component to limit diffusion of the boron in the gate electrode film.

Embodiments of the present disclosure will be described hereinafter with reference to the drawings. The present embodiments are not intended to limit the present disclosure.

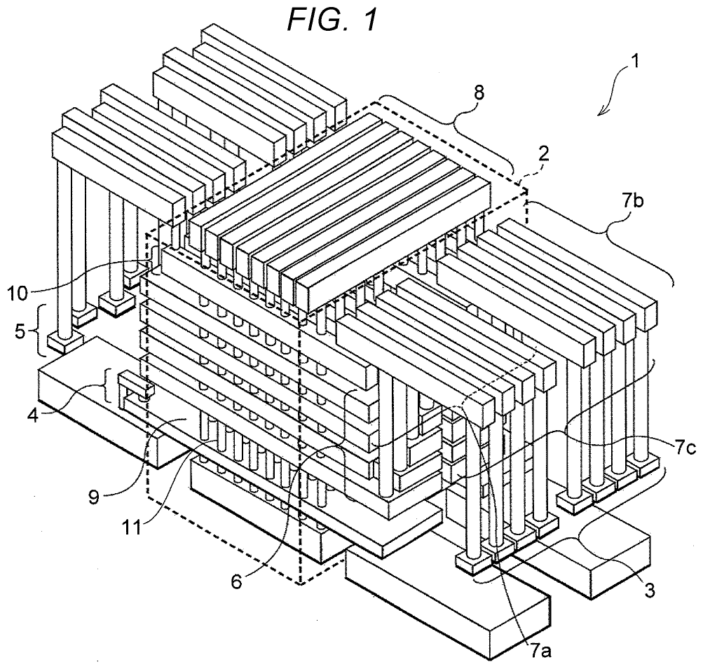

FIG. 1 is a perspective view depicting a schematic configuration of a semiconductor storage device according to a first embodiment. A semiconductor storage device 1 according to the present embodiment is a three-dimensionally stacked semiconductor storage device. Hereinafter, a structure of this semiconductor storage device 1 will be briefly described.

The semiconductor storage device 1 depicted in FIG. 1 includes a memory region 2, drive circuits 3, 4, and 5, word lines 6, lead lines 7a, 7b, and 7c, bit lines 8, select transistors 9 and 10, memory films 11, and the like.

In the memory cell region 2, the word lines 6 are stacked. In addition, the columnar memory films 11 penetrate the word lines 6 and are arranged in a matrix configuration. The memory films 11 each include a charge storage layer and the like. An upper portion of each memory film 11 is connected to the bit lines 8. The numbers of the word lines 6 and the bit lines 8 may be changed depending on a memory capacity, a chip area, or the like.

In the present embodiment, end portions of the word lines 6 are formed in a stepped configuration. The lead lines 7a are connected to the end portions of the word lines 6. Upper portions of the lead lines 7a are connected to the lead lines 7b. Furthermore, one end of each lead line 7b is connected to a corresponding lead line 7c. A lower end portion of each lead line 7c is connected to the drive circuit 3. The drive circuit 3 drives the word lines 6 via the lead lines 7a to 7c.

The select transistor 9 is disposed under the lowermost word line 6. The select transistor 9 is driven by the drive circuit 4. Furthermore, the select transistor 10 is disposed on the uppermost word line 6. The select transistor 10 is driven by a drive circuit 5.

The drive circuits 3, 4, and 5 are peripheral circuits disposed around the memory cell region 2. At least one of the drive circuits 3, 4, and 5 has a semiconductor device such as a P-channel MOS transistor. A structure of principal portions of this MOS transistor will be described below.

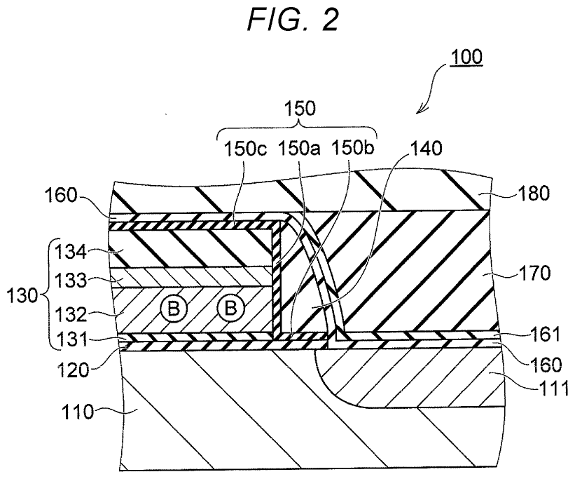

FIG. 2 is a cross-sectional view depicting the structure of the principal portions of the P-channel MOS transistor according to the first embodiment. A MOS transistor 100 depicted in FIG. 2 includes a semiconductor substrate 110, a diffusion layer 111, a gate insulating film 120, a gate electrode film 130, a side wall insulating film 140, a barrier film 150, a liner oxide film 160, a liner nitride film 161, an interlayer insulating film 170, and a nitride film 180.

The semiconductor substrate 110 is, for example, a silicon substrate. The diffusion layer 111 diffuses from portion of a front surface of the semiconductor substrate 110. Although not depicted in FIG. 2, one more diffusion layer 111 is formed in the MOS transistor 100 line-symmetrically about a center line in a short-length direction perpendicular to a long-length direction of the gate electrode film 130. One of these two diffusion layers 111 is a drain region and the other diffusion layer 111 is a source region.

The gate insulating film 120 is provided on the semiconductor substrate 110. The gate insulating film 120 is, for example, a silicon oxide (SiO₂) film.

The gate electrode film 130 is provided on the gate insulating film 120. In the present embodiment, the gate electrode film 130 is a stacked film that has an oxynitride film 131, a polysilicon film 132, a conductive film 133, and a nitride film 134.

The oxynitride film 131 is provided on the gate insulating film 120. The oxynitride film 131 is, for example, a silicon oxynitride (SiON) film. The polysilicon film 132 is provided on the oxynitride film 131. As depicted in FIG. 2, the polysilicon film 132 contains boron (B). Regulating a concentration of this boron makes it possible to reduce depletion of the gate electrode film 130.

The conductive film 133 is provided on the polysilicon film 132. The conductive film 133 contains, for example, tungsten (W) and silicon. The nitride film 134 is provided on the conductive film 133. The nitride film 134 is, for example, silicon nitride (SiN) film. The nitride film 134 can prevent diffusion of tungsten contained in the conductive film 133. The side wall insulating film 140 is opposed to a side surface of the gate electrode film 130 via the barrier film 150. The side wall insulating film 140 is, for example, a silicon oxide film.

The barrier film 150 is a film that contains carbon as a main component for preventing the diffusion of boron contained in the polysilicon film 132. The barrier film 150 may contain not only carbon but also silicon and nitrogen. As depicted in FIG. 2, the barrier film 150 has a first portion 150a, a second portion 150b, and a third portion 150c.

The first portion 150a is provided between the side surface of the gate electrode film 130 and the side wall insulating film 140. In other words, the first portion 150a is brought into contact with the side surface of the gate electrode film 130 and covered with the side wall insulating film 140.

The second portion 150b is provided between the gate insulating film 120 and a bottom surface of the side wall insulating film 140. In other words, the second portion 150b is brought into contact with an end portion of the gate insulating film 120 and covered with the side wall insulating film 140. When the second portion 150b extends toward each diffusion layer 111 beyond the gate insulating film 120, the second portion 150b is possibly brought into contact with contact plugs of the diffusion layer 111. A length of the second portion 150b is, therefore, preferably in a range in which the second portion 150b does not protrude from the gate insulating film 120.

The third portion 150c is provided on the gate electrode film 130. It is noted that the third portion 150c is not necessarily formed.

In the present embodiment, the second portion 150b is connected to the first portion 150a. Owing to this, the barrier film 150 has an L-shaped cross-sectional shape formed from the first portion 150a and the second portion 150b as depicted in FIG. 2.

The liner oxide film 160 covers the third portion 150c of the barrier film 150, the side wall insulating film 140, and the diffusion layer 111. The liner oxide film 160 is, for example, a silicon oxide film. The liner nitride film 161 covers the liner oxide film 160. The liner nitride film 161 is, for example, a silicon nitride film. The liner oxide film 160 and the liner nitride film 161 function as an etching stopper film when contact holes buried with the contact plugs (not depicted) connected to the gate electrode film 130 and the diffusion layers 111 are formed.

The interlayer insulating film 170 is provided on the liner nitride film 161. The interlayer insulating film 170 is, for example, a silicon oxide film. The nitride film 180 covers the liner oxide film 160 and the interlayer insulating film 170. The nitride film 180 is, for example, a silicon nitride film.

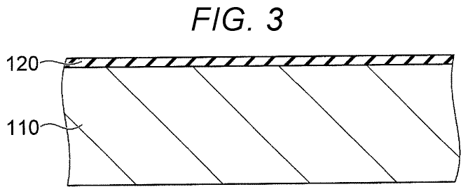

Portion of manufacturing processes for manufacturing the MOS transistor 100 described above will be described below with reference to FIGS. 3 to 7.

First, as depicted in FIG. 3, the gate insulating film 120 is formed on the semiconductor substrate 110. The gate insulating film 120 may be formed by, for example, forming a pattern by a photoresist after film formation and performing wet etching.

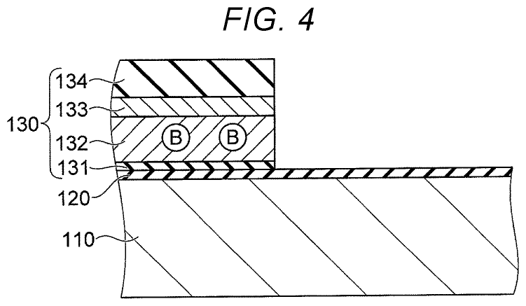

Next, as depicted in FIG. 4, the gate electrode film 130 is formed on the gate insulating film 120. When the gate electrode film 130 is formed, the oxynitride film 131 is formed by, for example, nitriding the gate electrode film 130. The polysilicon film 132, the conductive film 133, and the nitride film 134 are formed by, for example, Chemical Vapor Deposition (CVD) for supplying material gases for the films. It is noted that as for formation of the oxynitride film 131 depicted in FIG. 4, a portion that is formed on the gate insulating film 120 without being covered with the polysilicon film 132, that is, a portion exposed onto the gate insulating film 120 may be left.

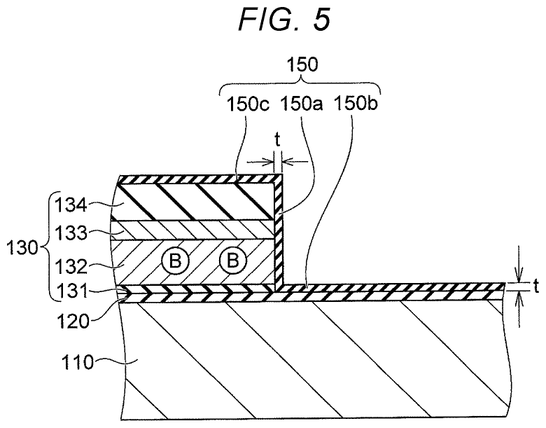

Next, as depicted in FIG. 5, the barrier film 150 is formed. In the present embodiment, the barrier film 150 is formed by, for example, a film formation process by the CVD, and an etching process for removing unnecessary film portions. In the film formation process, a first material gas containing silicon and a second material gas containing carbon and nitride are alternately supplied into a chamber. The first material gas includes, for example, hexachlorodisilane. The second material gas includes alkylamine such as triethylamine.

Since the barrier film 150 contains carbon as the main component, a carbon content is preferably equal to or higher than 1.0 atomic %. Furthermore, since nitrogen contained in the barrier film 150 can contribute to preventing the diffusion of boron, a carbon content is preferably equal to or lower than 70.0 atomic %. That is, the carbon content in the barrier film 150 falls in a range from 1.0 to 70.0 atomic %.

Moreover, if a volume of the barrier film 150 is large, then the barrier film 150 contacts other interconnections, possibly resulting in a manufacturing failure. As such, a thickness t of the barrier film 150 is equal to or smaller than 2 nanometers (nm).

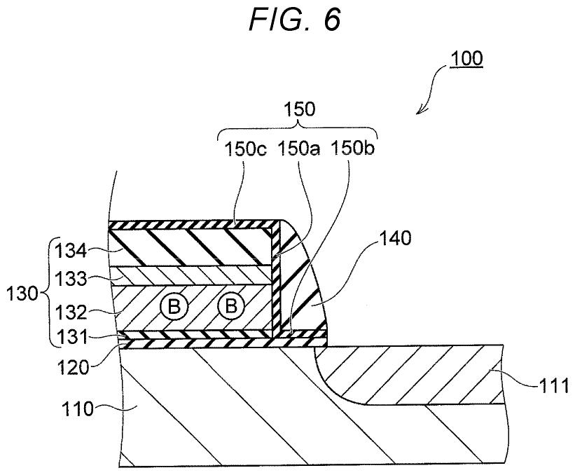

Next, as depicted in FIG. 6, the side wall insulating film 140 is formed on the first portion 150a and the second portion 150b. The side wall insulating film 140 is formed by, for example, a film formation process by the CVD and an etching process for removing unnecessary film portions by Reactive Ion Etching (RIE). In this etching process, the gate insulating film 120 and the barrier film 150 formed on the diffusion layers 111 are also removed. The diffusion layers 111 are formed by implanting boron ions. The liner oxide film 160, the liner nitride film 161, the interlayer insulating film 170, and the nitride film 180 are then formed in order. Since a normally used manufacturing method may be adopted as a method of manufacturing these films, the manufacturing method is not described herein.

After manufacturing the MOS transistor 100 described above, the memory cell region 2 and the like of the semiconductor storage device 1 are manufactured. At a time of manufacturing the memory cell region 2, a high-temperature heat treatment such as annealing is carried out. In this case, there is a concern of the diffusion of boron from a side surface of the polysilicon film 132 in the gate electrode film 130 to the semiconductor substrate 110 via the side wall insulating film 140 and the gate insulating film 120.

According to the present embodiment described above, however, the barrier film 150 containing carbon as the main component is provided around the gate electrode film 130. Owing to this, even if a concentration of boron contained in the polysilicon film 132 is high, it is possible to prevent the diffusion of boron. Thus, it is possible to prevent the diffusion of boron while reducing the depletion of the gate electrode film 130.

It is noted that the oxynitride film 131 is formed between a bottom surface of the polysilicon film 132 and the gate insulating film 120 in the present embodiment. Nitrogen contained in the oxynitride film 131 can prevent the diffusion of boron from the bottom surface of the polysilicon film 132 to the semiconductor substrate 110.

### Second Embodiment

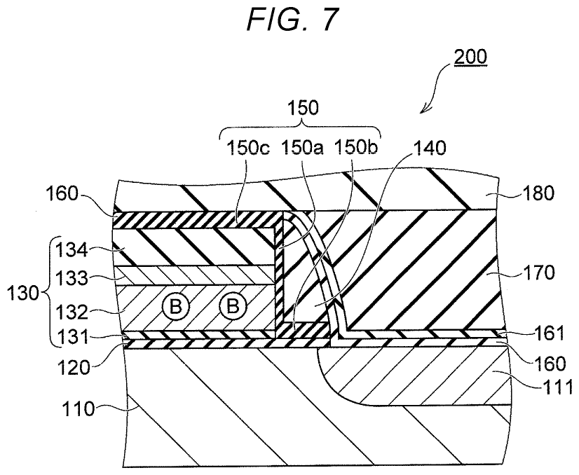

FIG. 7 is a cross-sectional view depicting a structure of principal portions of a P-channel MOS transistor according to a second embodiment. In FIG. 8, similar elements to those of the MOS transistor 100 according to the first embodiment depicted in FIG. 2 are denoted by the same reference signs and not described in detail.

In the barrier film 150 of a MOS transistor 200 depicted in FIG. 7, the second portion 150b is thicker than the first portion 150a. For the convenience of manufacturing, the third portion 150c is also formed thicker than the first portion 150a.

According to the present embodiment, a thickness of the second portion 150b is larger than that of the second portion 150b according to the first embodiment. This makes the diffusion of boron from the side surface of the polysilicon film 132 to the semiconductor substrate 110 more difficult. This can further enhance a boron diffusion prevention effect.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a gate insulating film provided on the semiconductor substrate;
a gate electrode film, provided on the gate insulating film, that includes boron;
a side wall insulating film extending along a side surface of the gate electrode film; and
a barrier film including a first portion provided between the side surface of the gate electrode film and the side wall insulating film and a second portion, connected to the first portion, that is provided between the gate insulating film and a bottom surface of the side wall insulating film,
wherein the barrier film includes carbon as a main component.

2. The semiconductor device according to claim 1, wherein
a carbon content of the carbon in the barrier film is between 1.0 and 70.0 atomic %.

3. The semiconductor device according to claim 1, wherein
the barrier film further includes silicon and nitrogen.

4. The semiconductor device according to claim 1, wherein
a thickness of the barrier film is equal to or less than 2 nanometers (nm).

5. The semiconductor device according to claim 1, wherein
a thickness of the second portion is greater than a thickness of the first portion.

6. A semiconductor device manufacturing method, comprising:
forming a gate insulating film on a semiconductor substrate;
forming a gate electrode film including boron on the gate insulating film; and
forming a barrier film including carbon as a main component along a side surface of the gate electrode film and over a portion of an upper surface of the gate insulating film.

7. The semiconductor device manufacturing method according to claim 6, wherein forming the barrier film further comprises:
alternately supplying a first gas including silicon and a second gas including carbon to form a film over the gate electrode film and the gate insulating film.

8. The semiconductor device manufacturing method according to claim 7, further comprising:
forming a diffusion layer, laterally adjacent to the gate electrode film, that extends into the semiconductor substrate; and
forming a side wall insulating film overlaying a side surface of the barrier film and a portion of an upper surface of the barrier film that covers the portion of an upper surface of the gate insulating film to expose the diffusion layer.

9. The semiconductor device manufacturing method according to claim 6, wherein
a carbon content of the carbon in the barrier film is between 1.0 and 70.0 atomic %.

10. The semiconductor device manufacturing method according to claim 6, wherein
the barrier film further includes silicon and nitrogen.

11. The semiconductor device manufacturing method according to claim 6, wherein
a thickness of the barrier film is equal to or less than 2 nanometers (nm).
